(19) United States
(12) Patent Application Publication
(10) Pub. No.: US 2008/0261478 A1
(43) Pub. Date: Oct. 23, 2008

(54) PATTERNING METHOD FOR LIGHT-EMITTING DEVICES

(76) Inventors: Ronald S. Cok, Rochester, NY (US); John W. Hamer, Rochester, NY (US); Steven A. Van Slyke, Pittsford, NY (US)

Correspondence Address: David Novais;Patent Legal Staff, Eastman Kodak Company, 343 State Street, Rochester, NY, 14650-2201, US

(21) Appl. No.: 11/736,115

(22) Filed: Apr. 17, 2007

(51) Int. Cl. H01J 9/12

(52) U.S. Cl. 445/24

(57) ABSTRACT

A method of forming a patterned, light-emitting device that includes providing a substrate, and mechanically locating a first masking film over the substrate. The first masking film is segmented into a first masking portion and one or more first contiguous opening portions in first locations. The first contiguous opening portions are mechanically removed. Subsequently, first light-emitting materials are deposited over the substrate in the first locations to form first light-emitting areas; and the first masking portion is mechanically removed.

### FIELD OF THE INVENTION

The present invention relates to light-emitting devices, and more particularly to a method for depositing light-emitting materials in a pattern over a substrate.

### BACKGROUND OF THE INVENTION

Organic light-emitting diodes (OLEDs) are a promising technology for flat-panel displays and area illumination lamps. The technology relies upon thin-film layers of organic materials coated upon a substrate. OLED devices generally can have two formats known as small molecule devices such as disclosed in U.S. Pat. No. 4,476,292, issued Oct. 9, 1984, by Ham et al., and polymer OLED devices such as disclosed in U.S. Pat. No. 5,247,190, issued Sep. 21, 1993, by Friend et al. Either type of OLED device may include, in sequence, an anode, an organic EL element, and a cathode. The organic EL element disposed between the anode and the cathode commonly includes an organic hole-transporting layer (HTL), an emissive layer (EL) and an organic electron-transporting layer (ETL). Holes and electrons recombine and emit light in the EL layer. Tang et al. (Applied Physics Letter, 51, 913 (1987), Journal of Applied Physics, 65, 3610 (1989), and U.S. Pat. No. 4,769,292, issued Sep. 6, 1988) demonstrated highly efficient OLEDs using such a layer structure. Since then, numerous OLEDs with alternative layer structures, including polymeric materials, have been disclosed and device performance has been improved. The use of inorganic light-emitting materials, for example quantum dot particles, is also known in the art.

Light is generated in an OLED device when electrons and holes that are injected from the cathode and anode, respectively, flow through the electron transport layer and the hole transport layer and recombine in the emissive layer. Many factors determine the efficiency of this light generating process. For example, the selection of anode and cathode materials can determine how efficiently the electrons and holes are injected into the device; the selection of ETL and HTL can determine how efficiently the electrons and holes are transported in the device, and the selection of EL can determine how efficiently the electrons and holes are recombined and emit light.

A typical OLED device uses a glass substrate, a transparent conducting anode such as indium-tin-oxide (ITO), a stack of organic layers, and a reflective cathode layer. Light generated from such a device may be emitted through the glass substrate. This is commonly referred to as a bottom-emitting device. Alternatively, a device can include a substrate, a reflective anode, a stack of organic layers, and a top transparent electrode layer. Light generated from such an alternative device may be emitted through the top transparent electrode. This is commonly referred to as a top-emitting device.

OLED devices can employ a variety of light-emitting organic materials patterned over a substrate that emit light of a variety of different frequencies, for example red, green, and blue, to create a full-color display. For small molecule organic materials, such patterned deposition is done by evaporating materials and is quite difficult, requiring, for example, expensive metal shadow-masks. Each mask is unique to each pattern and device design. These masks are difficult to fabricate and must be cleaned and replaced frequently. Material deposited on the mask in prior manufacturing cycles may flake off and cause particulate contamination. Moreover, aligning shadow-masks with a substrate is problematic and often damages the materials already deposited on the substrate. Further, the masks are subject to thermal expansion during the OLED material deposition process, reducing the deposition precision and limiting the resolution and size at which the pattern may be formed.

Alternatively, it is known to employ a combination of emitters, or an unpatterned broad-band emitter, to emit white light together with patterned color filters, for example, red, green, and blue, to create a full-color display. The color filters may be located on the substrate, for a bottom-emitter, or on the cover, for a top-emitter. For example, U.S. Pat. No. 6,392,340 entitled “Color Display Apparatus Having Electroluminescence Elements” issued May 21, 2002, by Yoneda et al., illustrates such a device. However, such designs are relatively inefficient since approximately two-thirds of the light emitted may be absorbed by the color filters.

The use of polymer masks, rather than metal, is known in the prior art. For example, WO2006/111766, published Oct. 26, 2006, by Speakman et al., describes a method of manufacturing, comprising applying a mask to a substrate; forming a pattern in the mask; processing the substrate according to the pattern; and mechanically removing the mask from the substrate. A method of manufacturing an integrated circuit is also disclosed. However, this method creates significant particulate contamination that can deleteriously affect subsequent processing steps, for example, the deposition of materials or encapsulation of a device. Moreover, subsequent location of a mask over a previously patterned area may damage materials in the previously patterned area.

Patterning a flexible substrate within a roll-to-roll manufacturing environment is also known and described in US2006/0283539, published Dec. 21, 2006, by Slafer et al. However, such a method is not readily employed with multiply patterned substrates employing evaporated deposition. Disposable masks are also disclosed in U.S. Pat. No. 5,522,963, issued Jun. 4, 1996, by Anders, Jr. et al., and a process of laminating a mask to a ceramic substrate described. However, the process of registering a mask to the substrate is limited in registration and size. A self-aligned process is described in U.S. Pat. No. 6,703,298, issued Mar. 9, 2004, by Roizin et al., for making memory cells. A sputtered disposable mask is patterned and removed by etching. However, as with the prior-art disclosures cited above, the formation of the mask and its patterning with multiple masking, deposition, and processing steps, are not compatible with delicate, especially organic, materials such as are found in OLED displays.

There is a need, therefore, for an improved method for patterning light-emitting materials that improves resolution and efficiency, reduces damage to underlying layers, reduces particulate contamination, scales to large-size substrates, and reduces manufacturing costs.

### SUMMARY OF THE INVENTION

The need is met, in accordance with one embodiment of the present invention, by providing a method of forming a patterned, light-emitting device that includes providing a substrate, and mechanically locating a first masking film over the substrate. The first masking film is segmented into a first masking portion and one or more first contiguous opening portions in first locations. The first contiguous opening portions are mechanically removed. Subsequently, first light-emitting materials are deposited over the substrate in the first locations to form first light-emitting areas; and the first masking portion is mechanically removed.

### Advantages

The method of the present invention has the advantage that it improves resolution and efficiency, reduces damage to underlying layers, reduces particulate contamination, scales to large-size substrates, and reduces manufacturing costs for a light-emitting device.

### BRIEF DESCRIPTION OF THE DRAWINGS

FIG. 1 is a flow chart illustrating a method of forming a patterned, light-emitting device according to one embodiment of the present invention;

FIG. 2 is a top view of light-emitting elements and a contiguous opening portion according to an embodiment of the present invention;

FIG. 3 is a top view of a three-color pixel stripe layout on a substrate according to the prior art;

FIG. 4 is a top view of a three-color-pixel offset layout on a substrate according to the prior art;

FIGS. 5A-C are top views of three different mask films for depositing different materials on a substrate useful for the present invention;

FIG. 6 is a three-dimensional view of a mask-film roll, mask film, material ablation device, and substrate useful for the present invention;

FIG. 7 is an exploded, three-dimensional view of a mask film, material ablation device, and substrate useful for the present invention;

FIG. 8 is a three-dimensional view of a patterned mask film, material ablation device, and substrate useful for the present invention;

FIG. 9 is an exploded three-dimensional view of a patterned mask film, material deposition device, and substrate useful for the present invention;

FIG. 10 is a three-dimensional view of a patterned mask film and a substrate with a raised area useful for the present invention;

FIG. 11 is a three-dimensional view of a mask film having an adhesive layer useful for the present invention;

FIG. 12 is a top view of a light-emitting element, patterned adhesive area, and exposure path useful for the present invention;

FIG. 13 is a three-dimensional view of a device for evaporating material through contiguous opening portions in a mask film useful for the present invention;

FIG. 14 is a three-dimensional view of contaminating particles within a light-emitting area, and an ablation device useful for the present invention;

FIGS. 15A-15C are top views of a mask film and contiguous opening portions in a stripe pattern according to an embodiment of the present invention;

FIG. 16 is a top view of a mask film and contiguous opening portions in a stripe pattern of light-emitting elements according to an embodiment of the present invention;

FIG. 17 is a top view of a mask film, contiguous opening portions, patterned adhesive, and exposure path in a stripe of light-emitting elements according to an embodiment of the present invention; and

FIG. 18 is a top view of a mask film and contiguous opening portions in an offset pattern of light-emitting elements according to an embodiment of the present invention.

It will be understood that the figures are not to scale since the individual components have too great a range of sizes and thicknesses to permit depiction to scale.

### DETAILED DESCRIPTION OF THE INVENTION

Referring to FIG. 1, in accordance with one embodiment of the present invention, a method of forming a patterned, light-emitting device comprises the steps of providing 100 a substrate, mechanically locating 105 a first masking film over the substrate, segmenting 110 the first masking film into a first masking portion and one or more first contiguous opening portions in first locations, mechanically removing 115 the one or more first contiguous opening portions 115, depositing 120 light-emitting materials over the substrate in the first locations 120 to form light-emitting areas, and mechanically removing 125 the first masking portion. In a further embodiment of the present invention, the steps of FIG. 1 are repeated for a second masking film over the same substrate by mechanically locating a second masking film with different locations for contiguous opening portions.

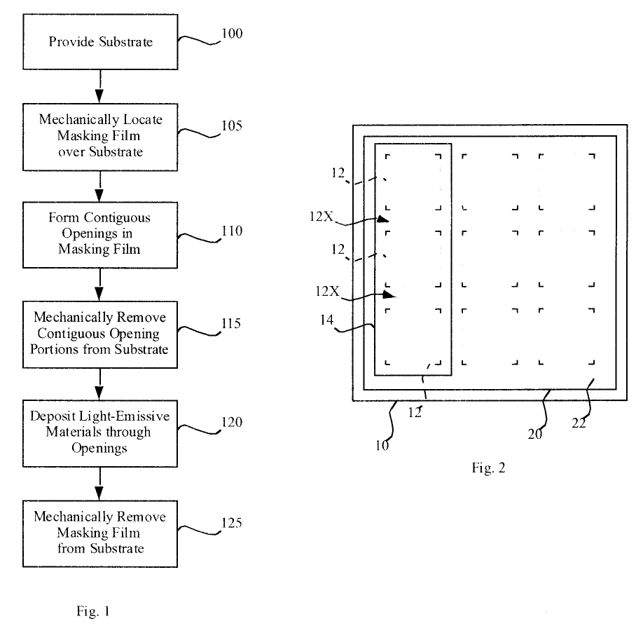

According to the present invention, a contiguous opening portion of a masking film is a single opening or hole in the masking film over two or more different, non-contiguous light-emitting areas. The perimeter of the contiguous opening portions is a simple closed curve. Referring to FIG. 2, for example, display devices typically have a plurality of light-emitting elements having light-emitting areas 12 located over different locations on a substrate 10. A contiguous opening portion 14 in a masking film 20, according to the present invention, is a contiguous opening in the masking film 20 that covers at least two different light-emitting areas 12 separated by a non-light emitting area 12X. The remainder of the masking film 20 comprises the masking portion 22 of the masking film 20. Since the light-emitting areas 12 are typically not themselves contiguous, the contiguous opening portions 14 will typically also cover a non-light-emitting portion 12X of the substrate 10 that is not light-emitting.

The masking films 20 employed in multiple different deposition steps may be identical. However, in most embodiments of the present invention, the contiguous opening portions 14 in the masking film 20 may be formed in different locations so that different light-emitting materials and elements may be deposited in different locations over the substrate 10. Moreover, more than one light-emitting material may be deposited through the contiguous opening portions, as may other materials deposited in layers over the same location on the substrate 10 as the light-emitting materials. For example, the light-emitting materials may comprise a plurality of light-emitting layers. The light-emitting materials may be organic materials comprising a small-molecule or polymer molecule light-emitting diodes. Alternatively, the light-emitting materials may be inorganic and comprise, for example, quantum dots. Other layers may comprise charge-control layers such as, for example, hole-injection, hole-transport, hole-blocking, electron-injection, electron-blocking, and electron-transport layers, as well as buffer layers.

According to various embodiments of the present invention, the opening portions of the mask film allow the deposition of light-emitting materials into the exposed locations. At the same time, the masking portions of the mask film protect the remainder of the area over the substrate from undesirable deposition and particulate contamination caused by the segmenting of the second masking film. Deposition of material into the exposed locations includes evaporating, spray coating, slide coating, hopper coating, or curtain coating materials over the substrate in the exposed locations.

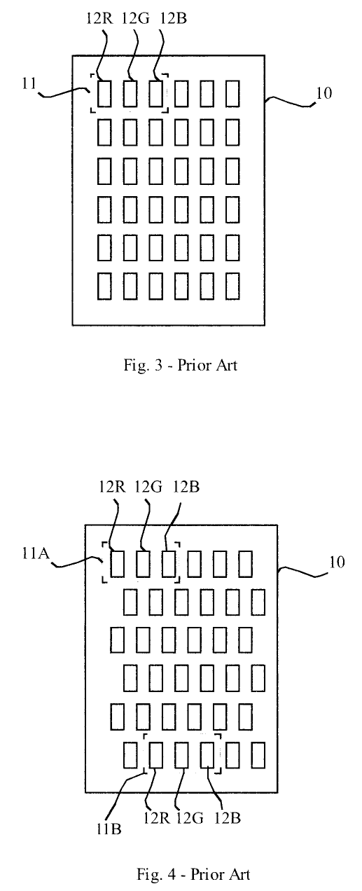

Referring to FIG. 3, in a prior-art design, pixels 11 may comprise three, patterned, light-emitting areas 12R, 12G, 12B, each patterned light-emitting area 12 comprising a sub-pixel emitting light of a different color, for example red, green, and blue, to form a full-color display. In other designs, four-color pixels are employed, for example including a fourth white, yellow, or cyan light-emitting area. The present invention includes any patterned light-emitting device.

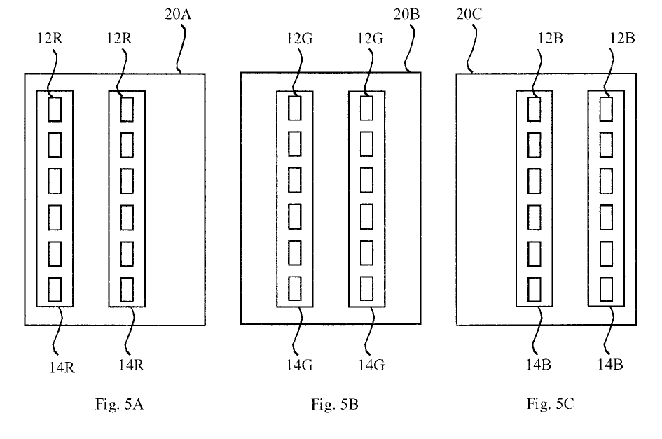

As shown in FIG. 3, the light-emitting elements 12R, 12G, 12B are arranged in a stripe configuration such that each color of light-emitting area forms a column of light-emitting areas emitting the same color of light. Referring to FIG. 4, in another prior-art design, the light-emitting areas 12 are arranged in delta patterns in which common colors are offset from each other from one row to the next row to form offset pixels 11A and 11B. Alternatively, four-element pixels may be arranged in two-by-two groups of four light-emitting elements (not shown). All of these different designs and layouts may be formed by the method of the present invention, regardless of design, layout, or number of light-emitting areas per pixel or colors of light-emitting areas and specifically includes displays having red, green, and blue sub-pixels and displays having red, green, blue, and white sub-pixels.

As taught in the prior art, for example, in manufacturing light-emitting devices, deposition masks may be made of metal and are reused multiple times for depositing evaporated organic materials. The masks may be cleaned but are, in any event, expensive, subject to thermal expansion, difficult to align, and problematic to clean. Moreover, the masks eventually wear out.

The present invention does not employ photolithographic methods of liquid coating, drying, patterned exposure forming cured and uncured areas, followed by a liquid chemical removal of the cured or uncured areas to form a pattern. In contrast, the present invention provides a very low-cost, single-use mask that is patterned while in place over the substrate, thereby overcoming the limitations of the prior art. The masks may be formed of flexible thin films of, for example, polymers, either transparent or non-transparent and may be patterned in a completely dry environment, that is, no liquid chemicals must be employed.

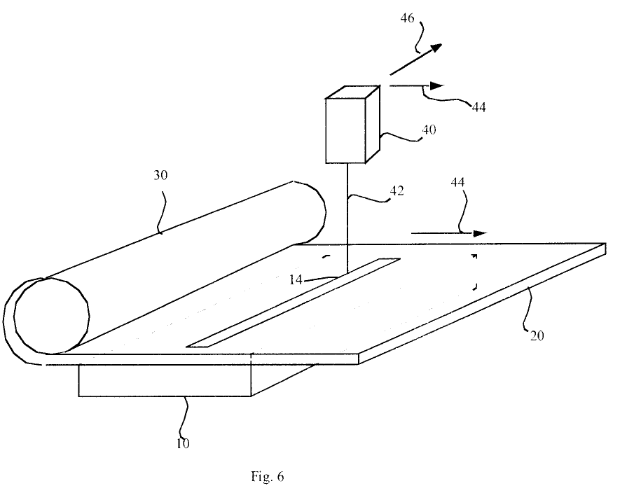

Referring to FIGS. 5A, 5B, and 5C, in one embodiment of the method of the present invention, three masks are successively employed. Each mask has one or more contiguous opening portions in different locations that are referred to as “mask holes”. Throughout this patent application “mask holes” and “contiguous opening portions” in the mask are used interchangeably. Three different types of material are deposited through mask holes 14R, 14G, 14B in three different sets of locations corresponding to the light-emitting element locations 12R, 12G, and 12B in the previously described layout of FIG. 3. In this embodiment, a first masking film 20A is firstly located over the substrate and segmented into a masking portion and a contiguous opening portion (mask hole). The material in the patterned mask holes 14R in the masking film 20A is mechanically removed. Light-emitting material is then deposited through the mask holes 14R onto the corresponding substrate light-emitting area locations 12R; the first masking film 20A is subsequently mechanically removed. In a second series of steps, a second masking film 20B is secondly located over the substrate and segmented. The material in the patterned mask holes 14G in the masking film 20B is mechanically removed. Light-emitting material is then deposited through the openings 14G onto the corresponding substrate light-emitting area locations 12G and the second masking film 20B subsequently mechanically removed. The pattern of mask holes in the first and second mask films may be different to expose different light-emitting areas and different light-emitting materials are typically deposited in the different areas. In a third series of steps, a third masking film 20C is thirdly located over the substrate and segmented. The material in the mask holes 14B in the masking film 20C is mechanically removed. Light-emitting material (different from that deposited through mask holes 14R and 14G) is then deposited through the mask holes 14B in yet another different pattern onto the corresponding substrate light-emitting area locations 12B and the third masking film 20C subsequently mechanically removed. At this stage, three different materials are patterned in three different sets of light-emitting area locations 12R, 12G, and 12B over the substrate to form a plurality of full-color light-emitting pixels. Any remaining processing steps necessary to form a complete device may then be performed. For example, an OLED device using patterned OLED materials may be employed in either a top- or bottom-emitter configuration. Note that the present invention may be combined with the unpatterned deposition of other layers to form a complete light-emitting device. Such unpatterned materials may include charge-injection layers and charge-transport layers, for example as are known in the organic and inorganic LED arts. Alternatively, all of the layers may be patterned. Moreover, the areas of the mask holes 14 may be larger than the light-emitting areas 12 (as shown). Since the light-emitting areas 12 are typically defined by patterned device electrodes (not shown), it is only necessary to deposit material over the electrode areas corresponding to light-emitting elements 12. Additional material may be deposited elsewhere to ensure that deposition tolerances are maintained.

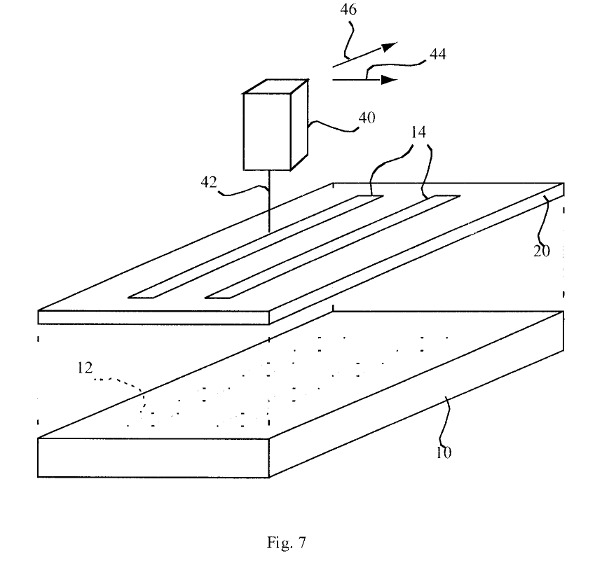

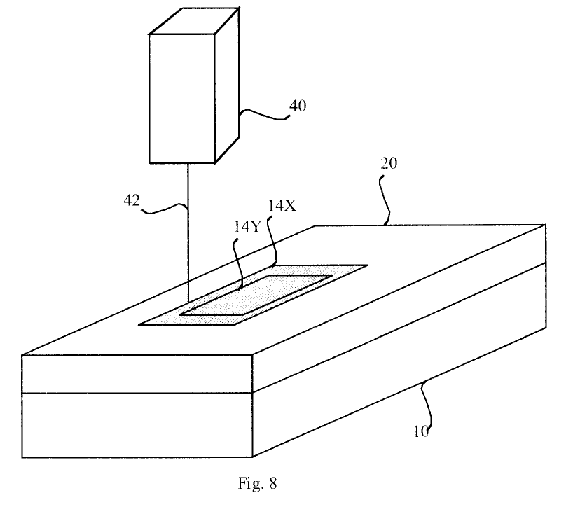

In one embodiment of the present invention, the contiguous opening portions may be segmented from the masking film by removing the mask film material from the perimeter of the contiguous openings in the masking film. This may be done by heating the masking film material, for example, by laser ablation, or by chemically treating the masking film. Referring to FIG. 6, a laser 40 emitting laser light 42 ablates the mask film material in the perimeter of the mask hole openings 14 in masking film 20 over substrate 10. The laser light 42 (or laser 40) is moved in orthogonal directions 44 and 46 to scan across the perimeter of the mask hole 14 and thereby ablate the material from the perimeter of mask hole 14. Alternatively, the substrate 10 may be moved in one direction while the laser beam 42 scans in the orthogonal direction, thereby enabling a continuous process. The masking film 20 may be dispensed from a roll 30 of masking film material and located over the substrate 10. Likewise, when the masking film 20 is removed, the mask film material may be mechanically picked up on a second roller (not shown) as new masking film material is advanced from the roller 30. Rolls of films, mechanisms for moving and locating the films over a substrate, lasers, and mechanisms for scanning lasers over a surface are all known in the art. FIG. 7 illustrates a more detailed exploded view including the laser 40, laser light 42, the scan directions 44 and 46, the masking film 20 over the substrate 10, and a plurality of mask holes 14 located over light-emitting elements 12.

While the masking film 20 need not itself be registered with the light-emitting areas 12 on the substrate 10, the mask hole openings 14 may correspond with the light emitting areas 12 and also be registered with them. Such registration may be aided by providing, for example, fiducial marks on the substrate. Such marks and the mechanisms for scanning lasers and ablating material to a necessary tolerance are known in the art, as are devices for collecting ablated material. Typical light-emitting areas 12 may be, for example, 40 microns by 100 microns in size.

In a more detailed illustration, referring to FIG. 8, the laser 40 scans laser light 42 around the perimeter 14X of the mask hole 14Y so that the masking film material in the interior of the mask hole 14Y is mechanically detached from the masking film 20. The segmented masking film material 14Y within the perimeter 14X may then be mechanically removed, thereby leaving the mask hole opening 14Y free for subsequent deposition of light-emitting material.

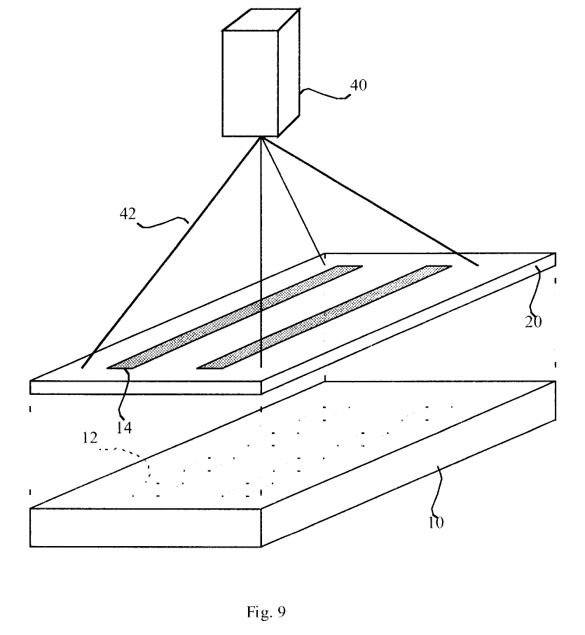

While FIGS. 6 and 7 illustrate embodiments in which a laser beam 42 is moved over the masking film 20 to form mask hole openings 14, FIG. 9 illustrates an alternative approach. Referring to FIG. 9, the masking film 20 includes light absorptive areas adapted to selectively absorb laser light so that ablation only occurs in the light-absorptive areas. Light-absorptive areas, in the locations of the perimeter of the mask hole openings 14, may be formed by printing light-absorbing materials on the masking film 20, for example, by inkjet or gravure processes, before or after the masking film 20 is located over the substrate 10. The light-absorptive areas correspond to the perimeter of masking holes 14. In this way, the entire masking film 20 (or portions thereof) may be exposed at one time to ablate material in the light-absorptive areas, thereby increasing the amount of material that may be ablated in a time period and decreasing the amount of time necessary to form the mask hole openings 14 in the masking film 20.

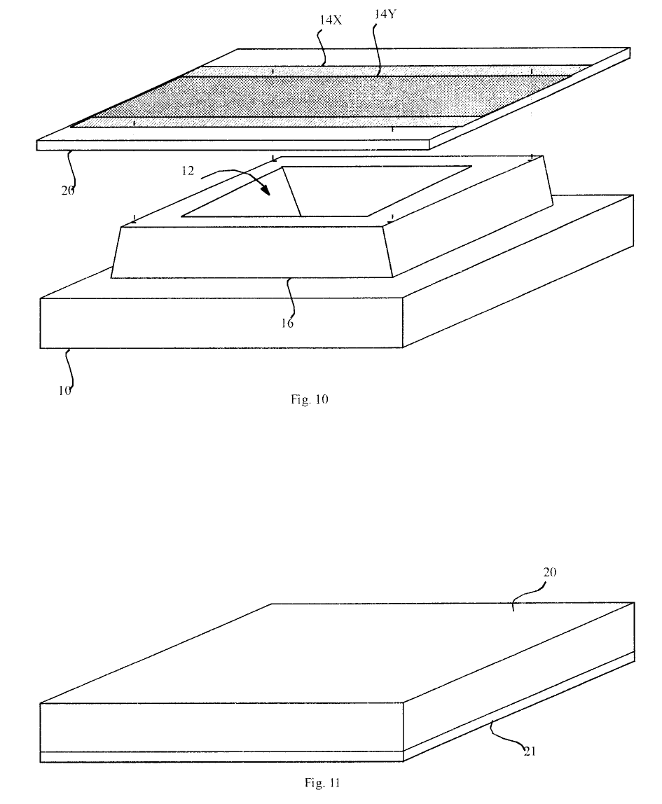

Referring to FIG. 10, in a further embodiment of the present invention, raised areas 16 may be formed over the substrate 10. Such raised areas 16 can comprise, for example, photolithographic materials such as photo-resist or silicon dioxides or silicon nitrides formed on the substrate 10 through photolithographic processes and may be, for example, 20 microns to 50 microns wide, depending on the tolerances of the processes used to pattern the substrate electrodes or thin-film electronic components formed on the substrate. The raised areas 16 may be located around a light-emitting area 12 and may be employed to insulate electrodes formed over the substrate 10. Such processes are well known in the photolithographic art and have been employed in, for example, OLED devices. The masking film 20 may be located over the substrate 10 and in contact with the raised areas 16. Laser ablation may be performed to detach the mask hole material by ablating masking film material in a portion of the perimeter 14X of the mask hole 14. The remaining masking film material 14Y is then detached. By employing a raised area 16, the masking film 20 is prevented from contacting the substrate 16 and any pre-existing layers located in the light-emitting areas 12.

As shown in FIG. 10, the mask hole perimeter 14X is located in part over the raised areas 16 (as shown by the dashed lines). In this embodiment, the laser light 42 is not directed into the light-emitting element area 12, thereby avoiding any problems that might result from exposing existing layers of material that may be already present in the light-emitting areas 12 (for example, inadvertent ablation of pre-deposited organic materials). Note that the area of the mask hole 14 may be larger than the light-emitting area 12. The illustrations of FIGS. 8, 9, and 10 show the substrate 10 below the masking film 20, however, the positions of the substrate 10 and masking film 20 may be reversed, so that detached materials may fall away from the masking film 20 to aid any mechanical removal.

In further embodiments of the present invention, the masking film 20 may be coated with a weak adhesive on one or both sides of the masking film 20 to assist in locating and maintaining the masking film 20 in registration with the substrate 10 and light-emitting areas 12. The adhesive may be located on the side of the masking film 20 that it is in contact with, and adjacent to, the substrate 10 or raised areas 16. The adhesive may prevent, for example, the masking film 20 from moving with respect to the substrate 10 and may also serve to prevent detached masking film material from moving or falling into the light-emitting area 12, thus improving the detached material removal process. In another embodiment of the present invention, the adhesive may not be activated when the mask film 20 is applied over the raised areas 16. Pressure supplied from, for example a roller or plate, may be employed to adhere the mask film 20 to the raised areas 16. In an alternative embodiment, the adhesive may be light- or heat-curable, and light or heat is applied to the portions of the mask film in contact with the raised areas 20. The patterned adhesive has the advantage of reducing adhesion to other layers coated on the substrate, for example the light-emitting materials. FIG. 11 illustrates a mask film 20 with an adhesive layer 21.

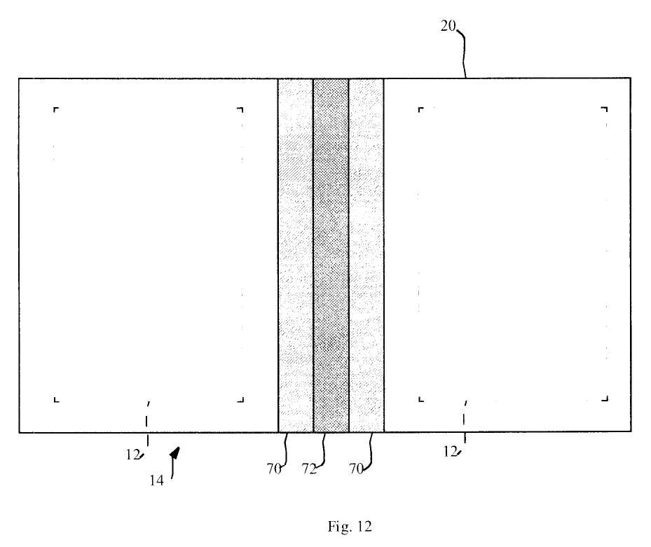

In a further embodiment of the present invention, the pattern-wise-activated adhesive layer 21 (shown in FIG. 11) may be activated in an area slightly larger than, and in registration with, the perimeter of the mask holes 14, so that the material at the edge of the holes may adhere to the raised areas 16, substrate 10, or layers coated on the substrate 10. Referring to FIG. 12, two adjacent light-emitting areas 12 are covered with mask film 20. Portion 70 of the mask film 20 is activated with adhesive to enable adhesion to the underlying surface between the light-emitting areas 12. The portion of the mask film material in a channel 72 is removed, for example, by ablation, so that the masking portion 22 of the mask film 20 may be segmented from the contiguous opening portion 14.

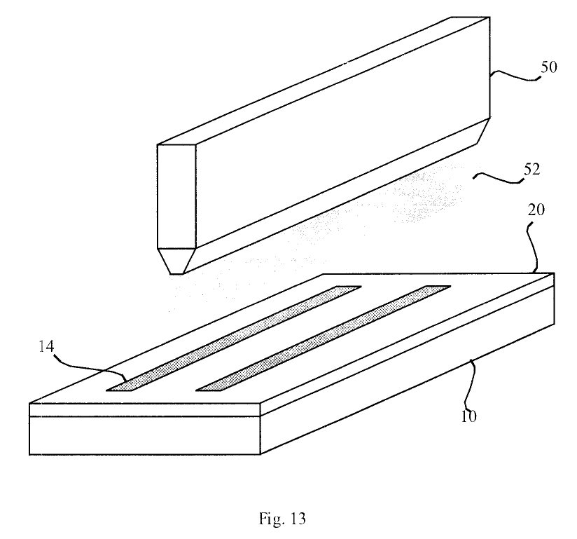

Referring to FIG. 13, once the mask hole openings 14 are formed in the masking film 20 in alignment with the light-emitting areas, light-emitting materials may be applied over the substrate through the mask hole 14. In the case of small molecule OLED devices, the light-emitting materials are typically deposited by evaporation in a vacuum from a source, for example, a linear source 50 that forms a plume of organic material 52 that is deposited through the mask holes 14 onto the substrate 10 in the locations of the light-emitters 12.

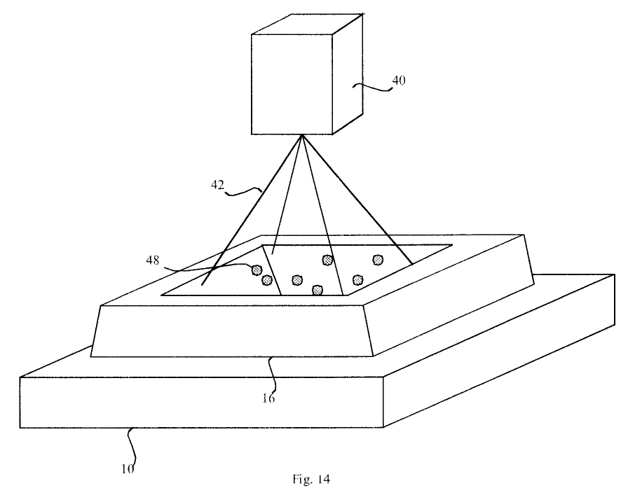

Referring to FIG. 14, particulate contamination 48 deposited in the light-emitting areas 12 within a raised area 16 may be ablated as well, for example by a laser. Alternatively, plasma cleaning or other chemical or mechanical cleaning may be employed if only layers compatible with such cleaning processes are present.

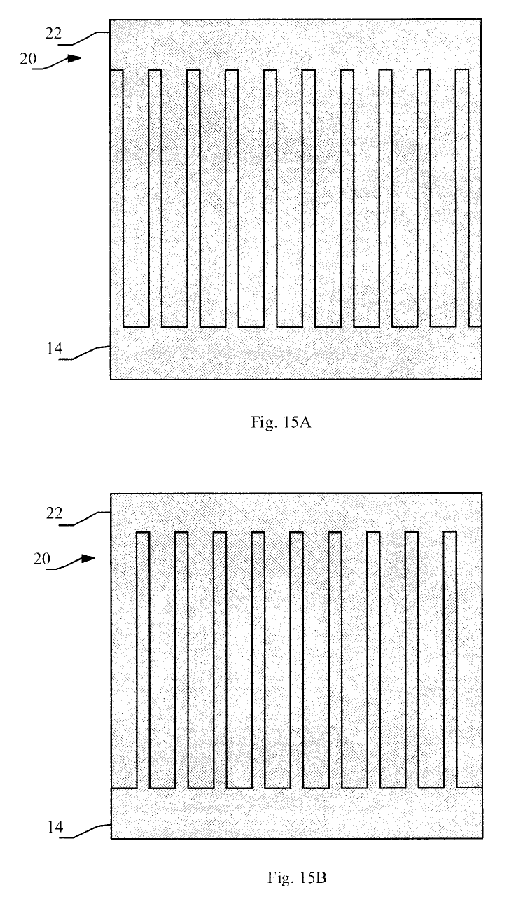

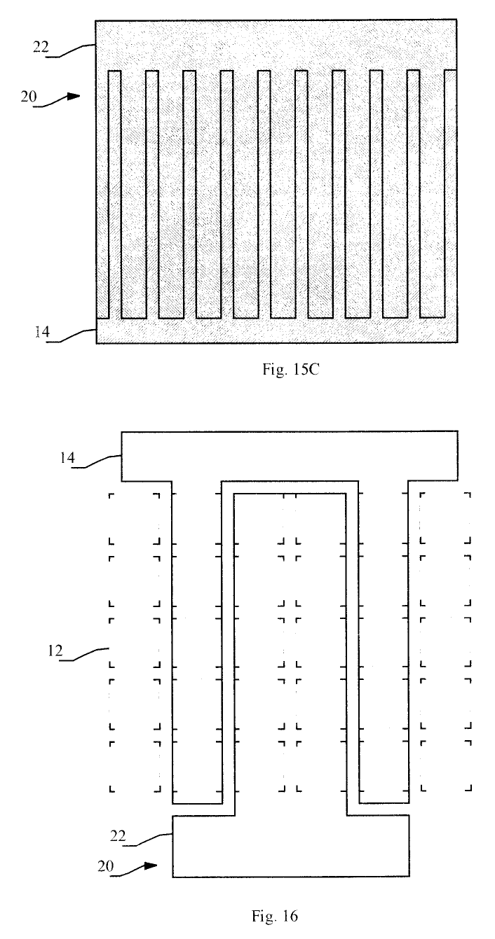

In further embodiments of the present invention, the contiguous opening portions may all be connected to form a single contiguous opening portion while leaving the remaining masking portion as another contiguous component. Having two contiguous elements simplifies mechanical removal of the segmented portions. Referring to FIG. 15A, a mask film 20 has a contiguous opening portion 14. The contiguous opening portion 14 corresponds in location to a plurality of stripes of light-emitting areas, for example, as shown in FIG. 5A. The stripes of the contiguous opening portion 14 are joined at one end of the stripes, while the remaining masking portion 22 is likewise joined at the other end to form two, segmented pieces of mask film. By mechanically removing contiguous opening portion 14, for example, by grasping the joined end in a nip and pulling the joined end up and away from an underlying substrate, the entire contiguous opening portion 14 may be removed; thereby exposing the stripes of light-emitting elements 12 in one operational step and enabling the deposition of light-emitting materials. The remaining masking portion 22 may be likewise removed. Such an approach reduces particulate contamination, since the light-emitting areas 12, on which deposition of light-emitting materials is not intended, are covered during the deposition step and any particulate contamination resulting from ablation of mask film material for detaching the contiguous opening portion will fall on the masking portion of the masking film 20 itself rather than into the light-emitting element areas 12. Moreover, mechanical removal of the masking portion or contiguous opening portion 14 is not likely to produce particulate contamination. Referring to FIGS. 15B and 15C, the operation of locating the mask film, detaching the contiguous opening portion from the mask film in stripes corresponding to stripes of light-emitting elements in different locations, removal of the contiguous opening portions, deposition of different light-emitting materials, and removal of the masking portion of the mask films are repeated.

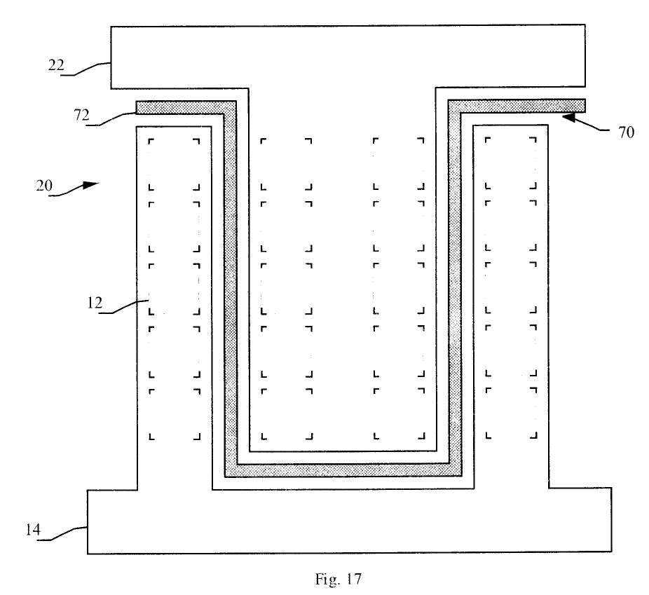

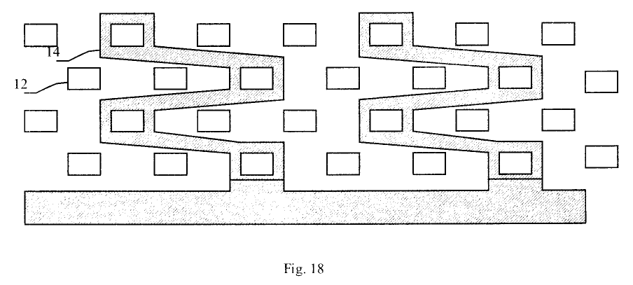

FIG. 16 illustrates the process in more detail. Referring to FIG. 16, light-emitting areas 12 are illustrated together with the mask film 20 and masking portion 22 covering two adjacent columns of light-emitting areas (for example red-light emitting and blue-light emitting areas), while the contiguous opening portion 14 covers two, non-adjacent stripes of light-emitting elements (for example green-light emitting). In a yet more detailed illustration of one embodiment of the present invention, FIG. 17 illustrates the path of an ablating laser employed to form a channel 72 to segment the masking portion 22 of the mask film 20 from the contiguous opening portion 14 and the underlying light-emitting elements 12. As discussed above, an adhesive, possibly patterned in an adhesive area 70, may also be employed. Referring to FIG. 18, a contiguous opening portion 14 is illustrated for an offset light-emitting area 12 pattern, wherein the contiguous opening portions are joined at one end of the offset light-emitting areas. In FIG. 18, the mask film is not shown, but can cover the remainder of the light-emissive areas. Note that in subsequent steps, the mask film areas may overlap each other so long as the light-emitting areas 12 are properly exposed or covered as the case may be. In such a case, light-emitting materials may be repeatedly deposited on non-light-emitting areas between the light-emitting areas 12. This arrangement may help the physical integrity of the contiguous opening portions 14.

The present invention provides many improvements over the prior art. The masking film may be inexpensive, for example, comprising for example PET (polyethylene teraphthalate) or other low-cost polymers provided in rolls. The film does not have to be repeatedly aligned with the substrate, as do traditional metal masks. Significant temperature dependencies may not arise, since the materials do not necessarily expand significantly in response to temperature; and if significant thermal expansion were to occur, the heat would only slightly decrease the area of the masking holes. If the masking holes are slightly oversized (as would be the case if a perimeter was ablated over a raised area), no effect on the formation of the light-emitting area would result. Because the film covers all of the substrate, except those areas to be patterned with light-emitting materials, the substrate is protected from particulate contamination. Moreover, because a new film is provided for each deposition cycle, particulate contamination formed by removing masking film material may be removed when the masking film is mechanically removed. Employing a raised area around the light-emitting areas likewise prevents damage to any pre-existing light-emitting areas, as does ablating a perimeter over the raised areas around mask holes. In any case, the masking film may be sufficiently thin that touching any delicate layers of, for example, organic materials, on the substrate may not damage the layers.

The present invention also provides a scalable means for manufacturing patterned light-emitting devices, since the masking film can be readily made in large sizes. Laser systems useful for ablating masking film materials may comprise many separate lasers, therefore enabling fast patterning. Such laser systems are known in the art. Mechanical removal of the mask film material enables fast turnaround on arbitrarily large substrates. The present invention can be employed in continuous processing systems.

The present invention may be practiced with either active- or passive-matrix organic or inorganic LED devices. It may also be employed in display devices or in area illumination devices. In one embodiment, the present invention is employed in a flat-panel OLED device composed of small molecule or polymeric OLEDs, as disclosed in, but not limited to U.S. Pat. No. 4,769,292, issued Sep. 6, 1988 to Tang et al.; and U.S. Pat. No. 5,061,569, issued Oct. 29, 1991 to VanSlyke et al. Many combinations and variations of organic light-emitting displays can be used to fabricate such a device, including both active- and passive-matrix OLED displays having either a top- or bottom-emitter architecture. Inorganic or polymer light-emitting materials may also be employed and patterned according to the method of the present invention.

The invention has been described in detail with particular reference to certain preferred embodiments thereof, but it will be understood that variations and modifications can be effected within the spirit and scope of the invention.

### PARTS LIST

10 substrate
11 pixel
12 light-emitting area or element
12R red light-emitting area
12G green light-emitting area
12B blue light-emitting area
12X non light-emitting area
14 mask hole, contiguous opening portion
14R opening in masking film for red light-emitter
14G opening in masking film for green light-emitter
14B opening in masking film for blue light-emitter
14X mask hole perimeter
14Y mask hole material within perimeter of mask hole
16 raised area
20, 20A, 20B, 20C masking film
21 adhesive layer
22 masking portion
30 roll of masking film
40 laser
42 laser light
44, 46 direction
48 contaminating particles
50 linear source
52 plume of evaporated particles
70 patterned adhesive area
72 channel
100 provide substrate step
105 locate masking film step
110 form contiguous opening portions step
115 mechanically remove contiguous opening portions step
120 deposit light-emitting materials step
125 mechanically remove masking film step

1. A method of forming a patterned, light-emitting device, comprising the steps of:
a) providing a substrate;
b) mechanically locating a first masking film over the substrate;
c) segmenting the first masking film into a first masking portion and one or more first contiguous opening portions in first locations;
d) mechanically removing the one or more first contiguous opening portions;
e) depositing first light-emitting materials over the substrate in the first locations to form first light-emitting areas; and
f) mechanically removing the first masking portion.

2. The method of claim 1, further comprising the steps of:
g) mechanically locating a second masking film over the substrate;
h) segmenting the second masking film into a second masking portion and one or more second contiguous opening portions, wherein the second contiguous opening portions are in one or more second locations over the substrate different from the first locations;
i) mechanically removing the one or more second contiguous opening portions;
j) depositing second light-emitting materials over the substrate in the second locations to form second light-emitting areas; and
k) mechanically removing the second masking portion.

3. The method of claim 2, wherein the second masking portion protects the first locations from particulate contamination caused by the deposition of second light-emitting materials or the segmenting of the second masking film.

4. The method of claim 1, wherein the step of depositing the light-emitting materials includes evaporating, spray coating, slide coating, hopper coating, or curtain coating materials over the substrate in the first locations.

5. The method of claim 1, wherein the light-emitting materials are organic materials including small-molecule or polymer molecule light-emitting diode materials or inorganic light emitting particles.

6. The method of claim 1, wherein the light-emitting areas form a striped pattern and the light-emitting materials in the stripe emit light of the same color.

7. The method of claim 6, wherein the first contiguous opening portion forms a plurality of separated stripes, and wherein the separated stripes are joined at one end of the stripes.

8. The method of claim 1, wherein the light-emitting areas form an offset pattern and the light-emitting materials in the offset light-emitting areas emit light of the same color.

9. The method of claim 8, wherein the first contiguous opening portions are joined at one end of the offset light-emitting areas.

10. The method of claim 1, wherein the step of segmenting the first masking film includes removing a channel of the first masking film from around a perimeter of the first contiguous opening portions in the masking film.

11. The method of claim 1, wherein the step of segmenting the first masking film includes ablating a channel of the first masking film with a patterned beam of light.

12. The method of claim 1, wherein the first masking film is light absorptive.

13. The method of claim 1, wherein the first masking film has an adhesive coated on the side of the first masking film adjacent the substrate.

14. The method of claim 13, wherein the adhesive is pattern-wise activated between the light-emitting areas.

15. The method of claim 14, wherein the adhesive is activated with a beam of light.

16. The method of claim 1, further comprising the step of removing particulate contamination from the first locations.

17. The method of claim 16, further comprising the step of removing particulate contamination from the first locations by laser ablation of particles, chemical cleaning, mechanical cleaning, or plasma cleaning.

18. The method of claim 1, further comprising the step of forming raised areas over the substrate between at least some of the light-emitting areas and locating the first masking film on the raised areas.

19. The method of claim 18, wherein the step of segmenting the first masking film includes forming a channel in the first masking film over the raised areas.

20. The method of claim 18, wherein the first masking film has an adhesive coated on the side of the first masking film adjacent the substrate and wherein the first masking film is adhered to at least a portion of the raised areas.
